(19) United States
(12) Patent Application Publication
(10) Pub. No.: US 2010/0302726 A1
(43) Pub. Date: Dec. 2, 2010

(54) ACTIVE THERMAL MODULE

(76) Inventor: Chin-Peng Chen, Sinjhuang City (TW)

Correspondence Address: NIKOLAI & MERSEREAU, P.A., 900 SECOND AVENUE SOUTH, SUITE 820, MINNEAPOLIS, MN, 55402, US

(21) Appl. No.: 12/476,416

(22) Filed: Jun. 2, 2009

(51) Int. Cl. H05K 7/20

(52) U.S. Cl. 361/679.47

(57) ABSTRACT

An active thermal module including a radiating chassis, a radiating fin assembly fixedly perpendicularly mounted on the radiating chassis, a heat pipe assembly and a fan. The heat pipe assembly penetrates through the radiating fin assembly. The heat pipe assembly includes one or more heat pipes each having a heat absorption section, a heat conduction section and a bending section between the heat absorption section and heat conduction section. The heat absorption sections horizontally attach to the radiating chassis in parallel to the heat conduction sections and the radiating chassis. The bending sections protrude from a lateral side of the radiating fin assembly and are exposed to outer side thereof. With the thermal module positioned in a limited space, the space can be fully utilized to increase heat dissipation area and enhance heat dissipation effect.

### FIELD OF THE INVENTION

The present invention relates to a thermal module, and more particularly to an active thermal module, in which the invalid ends of the heat pipes are not in contact with the radiating fin assembly. With the thermal module positioned in a limited space, the space can be fully utilized to increase heat dissipation area and enhance heat dissipation effect.

### BACKGROUND OF THE INVENTION

Following the rapid advance of electronic and information technologies, all kinds of electronic products (such as desktop computers and notebook computers) have been more and more popularly used and widely applied to various fields. As exemplified with a computer, there is a trend to increase processing speed and expand access capacity of the central processing unit (CPU) of the computer. Consequently, the CPU operates at higher and higher speed and at the same time generates heat at higher and higher heating power.

In order to avoid temporary or permanent failure of the computer due to overheating of the CPU, conventionally, a thermal module is directly disposed on the CPU to quickly dissipate the heat generated by the CPU to external environment so as to keep the CPU normally working.

Please refer to FIGS. 1 and 2. A conventional thermal module 1 includes a radiating chassis 11, a radiating fin assembly 12, a heat pipe 13 and a fan 14. The radiating chassis 11 is arranged on the CPU and has multiple fixing sections 111 extending from the radiating chassis 11. The radiating fin assembly 12 is disposed on the radiating chassis 11 between the fixing sections 111. The radiating fin assembly 12 includes multiple radiating fins 121 horizontally arranged and parallelly stacked up on the radiating chassis 11. The heat pipe 13 is arranged on the radiating chassis 11. The heat pipe 13 has a bight section 131 and two heat conduction sections 132 extending from two ends of the bight section 131 in a direction away from the radiating chassis 11. The bight section 131 attaches to the radiating chassis 11. The heat conduction sections 132 penetrate through the radiating fins 121 perpendicularly to the radiating chassis 11. The free ends of the heat conduction sections 132 protrude from the radiating fin assembly 12. The fan 14 is disposed between the fixing sections 111 on one side of the radiating chassis 11. The fan 14 is normal to the radiating chassis 11 and attaches to the radiating fin assembly 12. Accordingly, the radiating fin assembly 12 and the fan 14 are confined between the fixing sections 111. In order to avoid interference between the fan 14 and the fixing sections 111 of the radiating chassis 11, the fan 14 is arranged on the radiating chassis 11 to occupy the room for the radiating fin assembly 12. Therefore, the heat dissipation area and space are reduced. Moreover, in use, due to the limitation to the use space, it is impossible to enlarge the range of the radiating fins 121. Also, the free ends of the heat pipe 13 provide no heat conduction effect. Therefore, the radiating fins 121 must be arranged on the heat conduction sections 132 with the free ends of the heat conduction sections 132 protruding from the radiating fin assembly 12. As a result, the number of the radiating fins 121 of the radiating fin assembly 12 is reduced to decrease the heat dissipation area.

According to the aforesaid, the conventional thermal module has the following defects:

1. The number of the radiating fins is reduced.
2. The heat dissipation area is small.
3. The heat dissipation space can be hardly effectively used.
4. The heat dissipation effect is poor.

### SUMMARY OF THE INVENTION

A primary object of the present invention is to provide an active thermal module, which fully utilizes limited heat dissipation space to increase heat dissipation area.

A further object of the present invention is to provide the above active thermal module in which the invalid ends of the heat pipes are not in contact with the radiating fin assembly.

A still further object of the present invention is to provide the above active thermal module in which the fan is more compatibly installed.

A still further object of the present invention is to provide the above active thermal module which can more effectively conduct and dissipate heat.

To achieve the above and other objects, the active thermal module of the present invention includes a radiating chassis, a radiating fin assembly mounted on the radiating chassis, a heat pipe assembly and a fan. The radiating fin assembly includes multiple radiating fins fixedly perpendicularly disposed on the radiating chassis. The heat pipe assembly penetrates through the radiating fin assembly. The heat pipe assembly includes one or more heat pipes each having a heat absorption section, a heat conduction section and a bending section between the heat absorption section and heat conduction section. The heat absorption sections horizontally attach to the radiating chassis in parallel to the heat conduction sections and the radiating chassis. The heat conduction sections penetrate through the radiating fins. The bending sections protrude from a lateral side of the radiating fin assembly and are exposed to outer side thereof. The fan is mounted on the radiating chassis and attached to one side of the radiating fin assembly. The invalid ends of the heat pipes are not in contact with the radiating fin assembly. With the thermal module positioned in a limited space, the space can be fully utilized to increase heat dissipation area and enhance heat dissipation effect.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1 is a perspective assembled view of a conventional thermal module;

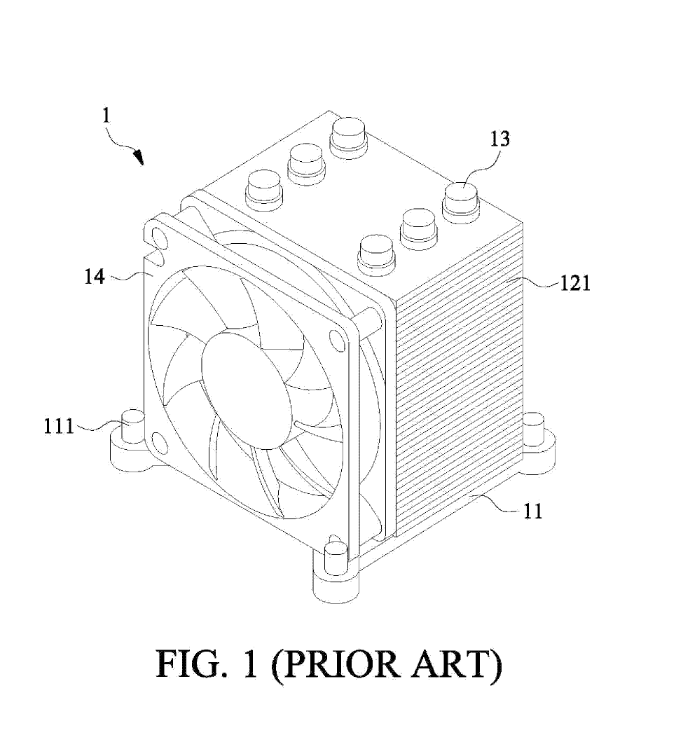

FIG. 2 is a perspective exploded view of the conventional thermal module;

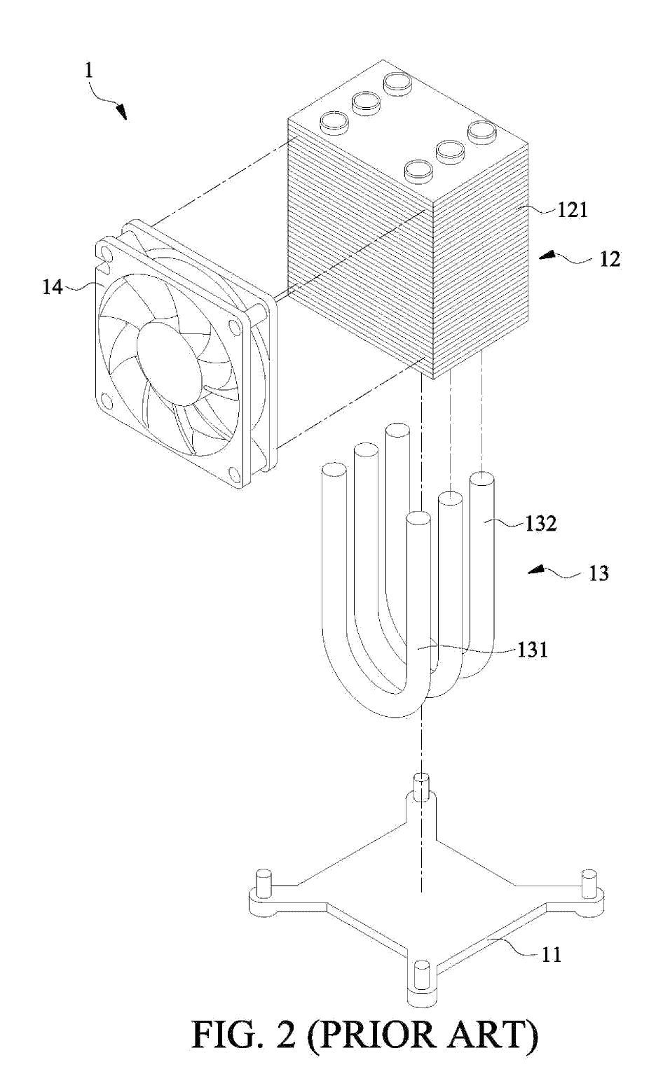

FIG. 3 is a perspective assembled view of a first embodiment of the thermal module of the present invention;

FIG. 4 is a perspective exploded view of the first embodiment of the thermal module of the present invention;

FIG. 5 is a perspective view according to FIG. 3, in which the number of the radiating fins is increased;

FIG. 6 is a perspective exploded view of a second embodiment of the thermal module of the present invention;

FIG. 7 is a perspective assembled view of the second embodiment of the thermal module of the present invention; and

FIG. 8 is a perspective view according to FIG. 7, in which the number of the radiating fins is increased.

### DETAILED DESCRIPTION OF THE PREFERRED EMBODIMENTS

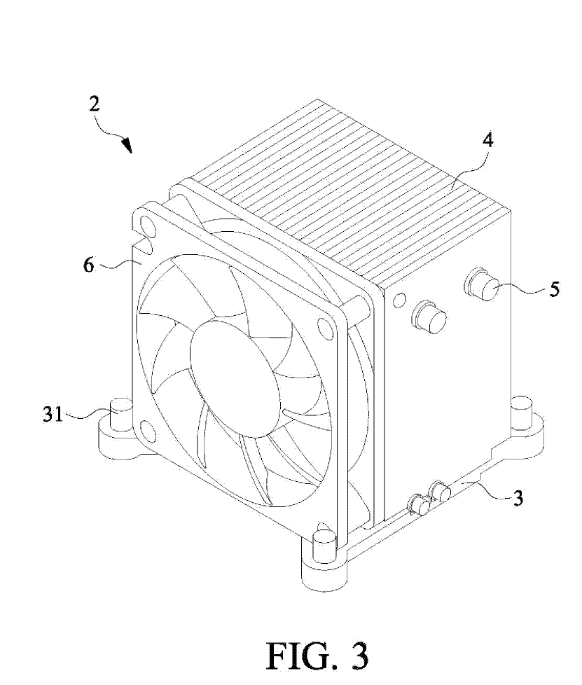

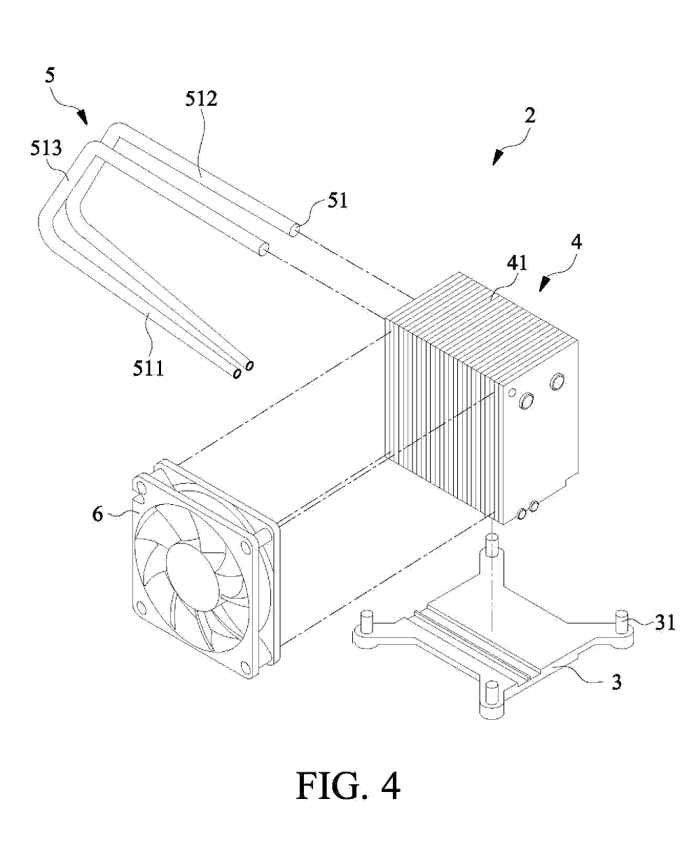

Please refer to FIGS. 3 and 4. According to a first embodiment, the active thermal module 2 of the present invention includes a radiating chassis 3, a radiating fin assembly 4, a heat pipe assembly 5 and a fan 6. The radiating chassis 3 has one or more fixing sections 31 arranged around the radiating chassis 3. The radiating fin assembly 4 is mounted on the radiating chassis 3. The radiating fin assembly 4 includes multiple radiating fins 41 fixedly perpendicularly disposed on the radiating chassis 3. The heat pipe assembly 5 penetrates through the radiating fin assembly 4. The heat pipe assembly 5 includes one or more heat pipes 51 each having a heat absorption section 511, a heat conduction section 512 and a bending section 513 between the heat absorption section 511 and heat conduction section 512. The heat absorption sections 511 horizontally attach to the radiating chassis 3, while the heat conduction sections 512 penetrate through the radiating fins 41 in parallel to the heat absorption sections 511 and the radiating chassis 3. The bending sections 513 protrude from a lateral side of the radiating fin assembly 4 and are exposed to outer side thereof. The fan 6 is mounted on the radiating chassis 3 and attached to the radiating fin assembly 4.

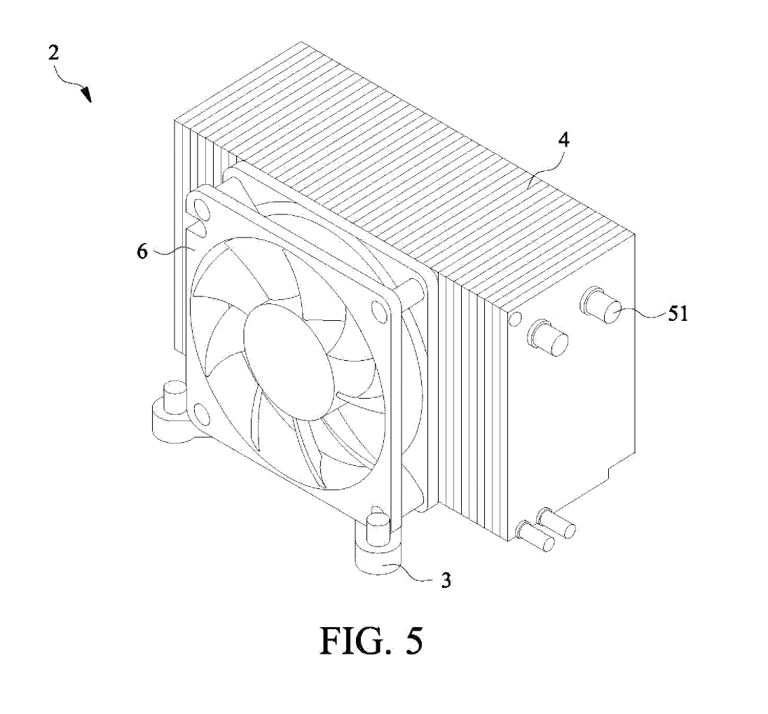

Please refer to FIGS. 3, 4 and 5. One side of the thermal module 2 opposite to the radiating fin assembly 4 is attached to a heat-generating unit (not shown). The heat-generating unit can be a CPU. When the heat-generating unit generates heat, the radiating chassis 3 conducts the heat to the heat absorption sections 511 of the heat pipes 51. The heat absorption sections 511 absorb the heat and transfer the heat to the bending sections 513. The free ends of the heat pipes 51 are invalid ends and exposed to outer side of the radiating fin assembly 4. The bending sections 513 can preliminarily dissipate part of the heat. The remainder of the heat is transferred to the radiating fin assembly 4 and further dissipated by the radiating fins 41 and the fan 6. The radiating fins 41 of the radiating fin assembly 4 are arranged on the radiating chassis 3 and normal thereto. The heat pipes 51 penetrate through the radiating fins 41. Accordingly, the number of the radiating fins 41 of the radiating fin assembly 4 can be increased. The length of the heat pipes 51 can be increased along with the increment of the number of the radiating fins 41 with the invalid ends exposed to outer side of the radiating fin assembly 4. Therefore, with the thermal module 2 positioned in a limited space, the space can be fully utilized to increase heat dissipation area and enhance heat dissipation effect.

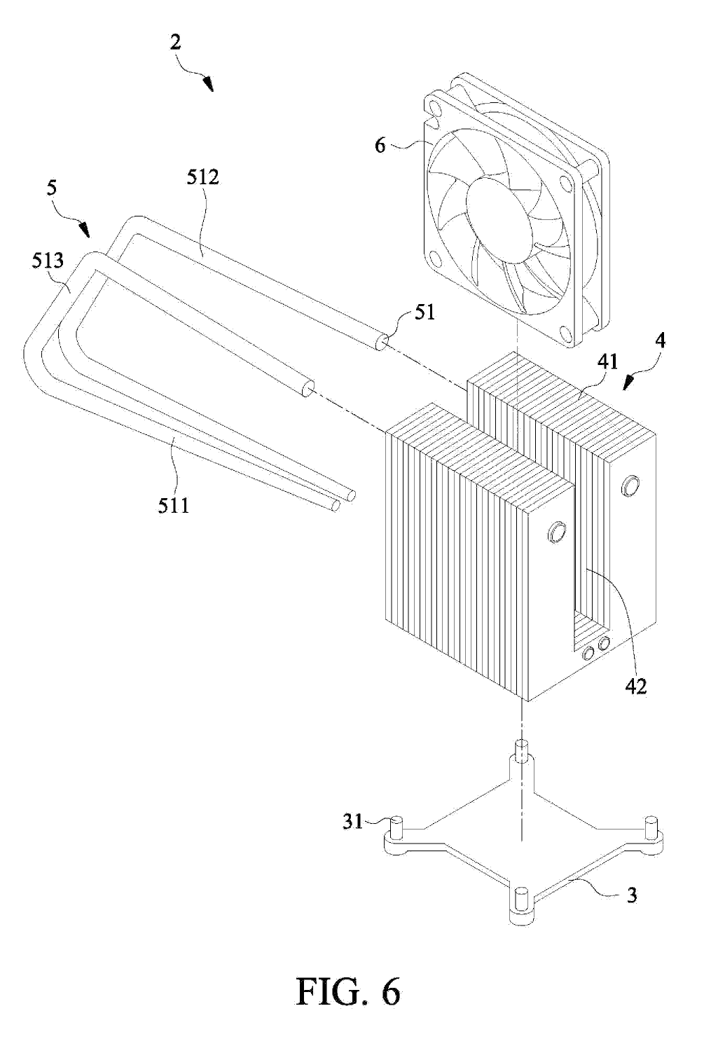

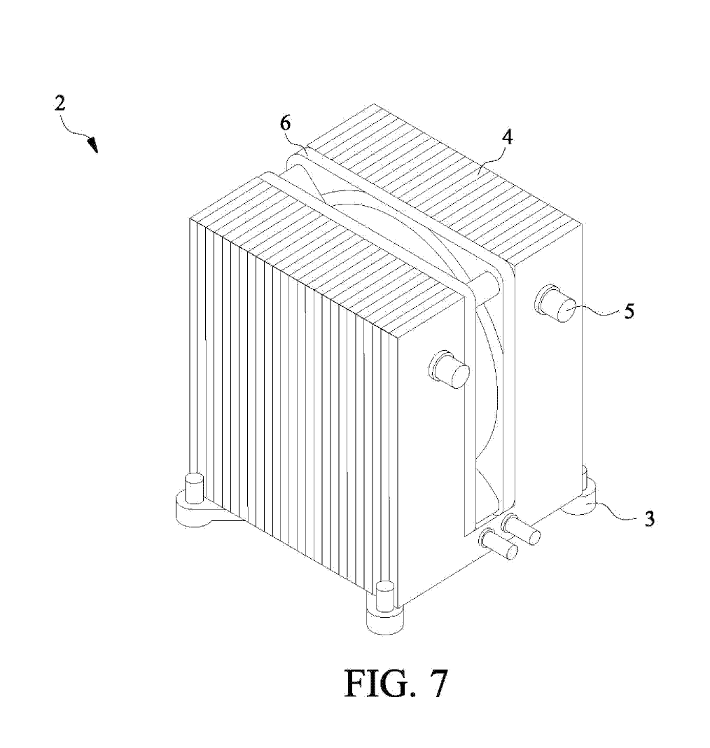

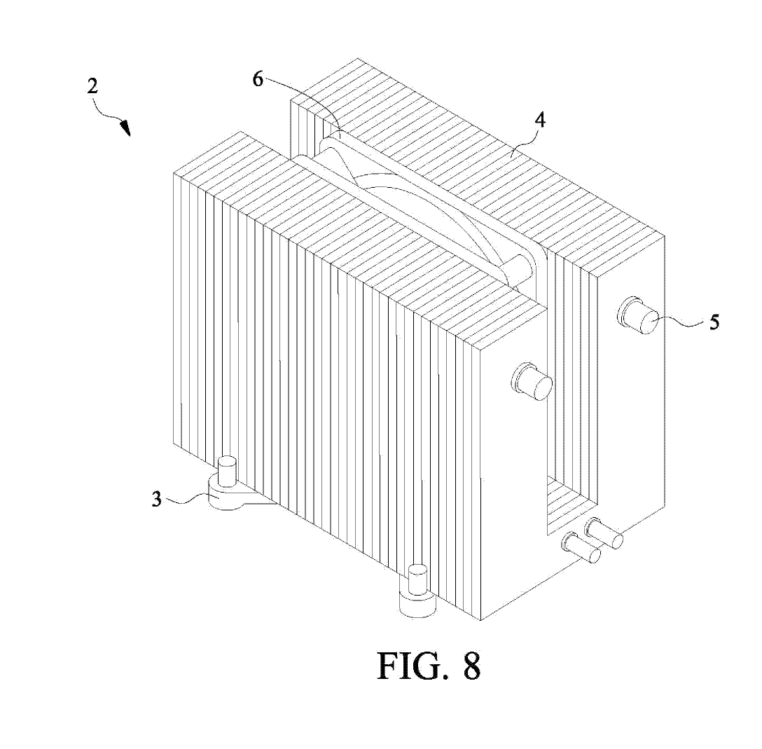

FIGS. 6, 7 and 8 show a second embodiment of the present invention. The radiating fin assembly 4 of the thermal module 2 includes multiple radiating fins 41 normal to the radiating chassis 3. The radiating fins 41 are horizontally arranged in parallel to each other. In addition, the radiating fin assembly 4 is formed with a passage 42 perpendicular to the radiating fins 41. The fan 6 is positioned in the passage 42. The heat pipes 51 of the heat pipe assembly 5 penetrate through two sides of the radiating fins 41 for conducting heat to the two sides of the radiating fins 41. The heat absorption sections 511 of the heat pipes 51 are attached to the radiating chassis 3. The heat conduction sections 512 penetrate through the radiating fins 41. A bending section 513 is formed between the heat absorption section 511 and heat conduction section 512. The bending section 513 protrudes from a lateral side of the radiating fin assembly 4 and is exposed to outer side thereof. One side of the thermal module 2 opposite to the radiating fin assembly 4 is attached to a heat-generating unit (not shown). When the heat-generating unit generates heat, the radiating chassis 3 conducts the heat to the heat absorption sections 511 of the heat pipes 51. The heat absorption sections 511 absorb the heat and transfer the heat to the bending sections 513. The bending sections 513 can preliminarily dissipate part of the heat. The remainder of the heat is transferred to the radiating fin assembly 4 and further dissipated by the radiating fins 41 and the fan 6. The number of the radiating fins 41 of the radiating fin assembly 4 and the length of the heat pipes 51 can be increased as necessary to increase heat dissipation area. The fan 6 can be compatibly positioned without interfering with the fixing sections 31 to fully utilize the heat dissipation space.

According to the aforesaid, the active thermal module of the present invention has the following advantages:

1. The number of the radiating fins can be increased as necessary.
2. The limited heat dissipation space can be fully utilized.
3. The heat dissipation area is increased.
4. The heat dissipation effect is better.
5. The fan is more compatibly installed.

The present invention has been described with some preferred embodiments thereof and it is understood that many changes and modifications in the described embodiments can be carried out without departing from the scope and the spirit of the invention that is intended to be limited only by the appended claims.

What is claimed is:

1. An active thermal module comprising:
a radiating chassis;
a radiating fin assembly including multiple radiating fins perpendicularly disposed on the radiating chassis; and
a heat pipe assembly including one or more heat pipes each having a heat absorption section and a heat conduction section, the heat absorption sections being connected with the radiating chassis, the heat conduction sections penetrating through the radiating fin assembly, the heat absorption sections being parallel to the heat conduction sections and the radiating chassis.

2. The active thermal module as claimed in claim 1, further comprising a fan mounted on the radiating chassis and attached to one side of the radiating fin assembly.

3. The active thermal module as claimed in claim 2, wherein the fan is mounted between two sides of the radiating fins and the heat conduction sections of the heat pipes penetrate through two sides of the radiating fins.

4. The active thermal module as claimed in claim 1, wherein the heat pipe has a bending section between the heat absorption section and heat conduction section.

5. The active thermal module as claimed in claim 4, wherein the bending section protrudes from one side of the radiating fin assembly and is exposed to outer side thereof.

6. The active thermal module as claimed in claim 1, wherein the radiating chassis has at least one fixing section.
